(19) United States
(12) Patent Application Publication
(10) Pub. No.: US 2026/0286519 A1
(43) Pub. Date: Sep. 24, 2026

(54) ATOMIC LAYER DEPOSITION DEVICE

(71) Applicant: HANWHA SOLUTIONS CORPORATION, Seoul (KR)

(72) Inventors: Byung Ju KANG, Seoul (KR); No Won KWAK, Seoul (KR); Hyun Woo KIM, Seoul (KR); Kwang Hyun CHOI, Seoul (KR); Jeong Ho SEO, Seoul (KR)

(21) Appl. No.: 19/100,636

(22) PCT Filed: May 18, 2023
(86) PCT No.: PCT/KR2023/006787

§ 371 Date: Feb. 3, 2025

(30) Foreign Application Priority Data
Aug. 3, 2022 (KR) 10-2022-0096752

(51) Int. Cl. C23C 16/455; C23C 16/46; C23C 16/52

(52) U.S. Cl. CPC C23C 16/45544; C23C 16/46; C23C 16/52

(57) ABSTRACT

An atomic layer deposition device according to an embodiment of the present invention includes: a chamber that accommodates a plurality of wafers; a plurality of heaters disposed on a surface of the chamber; and a control unit that controls the heaters, wherein the chamber is divided into a plurality of zones in a first direction defined as an extension direction of the chamber, the plurality of heaters are disposed in each of the plurality of zones of the chamber, and the control unit controls temperatures of the plurality of heaters separately.

### TECHNICAL FIELD

Embodiments of the present invention relate to an atomic layer deposition device.

### BACKGROUND ART

A atomic layer deposition (ALD) technology is a technology for depositing a thin film, i.e., a protective film, on a memory element of a semiconductor, that is, a technology of thermally decomposing gas flowing into a vacuum chamber and depositing the decomposed gas as an atomic layer. Incidentally, efforts are continuously made to improve a device and process for forming a high-quality thin film on a substrate.

Recently, technology for shortening a process time per wafer using a batch type deposition device that processes multiple wafers simultaneously with one deposition device has been developed.

An atomic layer deposition device includes a loading unit for supplying a wafer, a vacuum chamber unit for performing atomic layer deposition in a vacuum atmosphere, an outlet for discharging gas after a reaction, a frame for supporting the deposition device, a cover, etc.

In this case, uniform temperature transfer into the process chamber is required to thermally decompose the gas flowing into the vacuum chamber, and shortening the time to stably reach a desired temperature is also one of the factors to consider.

Generally, in an atomic layer deposition device, a heater is located inside or outside the chamber to provide heat to the chamber. However, when the heater is located inside the chamber, the lifetime of the heater can be reduced and the volume of the chamber can be increased. Accordingly, from the viewpoint of the cost and management associated with these problems, the heater is located outside the chamber in industrial applications of this device. The heater located outside the chamber is provided in a form that is inserted into an outer wall of the chamber or in a form that stands upright outside the chamber while spaced a certain distance from the chamber.

However, when the heater is inserted into the outer wall of the chamber, it is difficult to separate the heater from the chamber, and thus it is difficult to replace the heater or recycle the chamber. In addition, when the heater is disposed standing upright outside the chamber while spaced a certain distance from the chamber, the heat loss of the heater may increase due to the distance from the chamber, and there is a problem that uniform heat transfer into the chamber is not achieved.

### DISCLOSURE

### Technical Problem

An object of the present invention to be solved is to provide an atomic layer deposition device having a heater structure that enables easy replacement of a heater and allows heat to be uniformly transferred into the chamber.

However, the object is exemplary, and the object of the present invention is not limited thereto.

### Technical Solution

An atomic layer deposition device according to an embodiment of the present invention includes: a chamber that accommodates a plurality of wafers; a plurality of heaters disposed on a surface of the chamber; and a control unit that controls the heaters, wherein the chamber is divided into a plurality of zones in a first direction defined as an extension direction of the chamber, the plurality of heaters are disposed in each of the plurality of zones of the chamber, and the control unit controls temperatures of the plurality of heaters separately.

One zone of the plurality of zones of the chamber may include a left side portion, a right side portion, an upper side portion, and a lower side portion, the heater may be disposed on each of the left side portion, the right side portion, the upper side portion, and the lower side portion, and the control unit may control the heater disposed on each of the left side portion, the right side portion, the upper side portion, and the lower side portion separately.

In the one zone, shapes of the heaters disposed on the left side portion and the right side portion may be the same, and shapes of the heaters disposed on the upper side portion and the lower side portion may be the same.

A size of each zone located at outermost portions on both sides of the chamber among the plurality of zones may be smaller than a size of each zone located at portions excluding the outermost portions on both sides of the chamber.

The plurality of wafers may be disposed in zones excluding the zones located at the outermost portions on both sides of the chamber among the plurality of zones.

The plurality of zones may include a first zone that is closest to an insertion portion (IW) of the wafer, and a fifth zone that is farthest from the insertion portion (IW) of the wafer, and the control unit may set a temperature of the first zone higher than a temperature of the fifth zone.

A heating pipe (Hp) may be disposed in the plurality of heaters.

Each of the plurality of heaters may include a plurality of sub-heaters disposed in each of the plurality of zones of the chamber, the chamber may include a heater fixing portion that fixes the heater to the chamber, and the heater fixing portion may be disposed in a region corresponding to a region between the plurality of sub-heaters adjacent in the first direction.

The plurality of heaters may be attached to or detached from the chamber.

Other aspects, features, and advantages other than those described above will become apparent from specific contents for implementing the invention, claims, and drawings below.

### Advantageous Effects

In an atomic layer deposition device according to embodiments of the present invention, since a heater is attached to a surface of a process chamber, heat can be uniformly transferred into the chamber, thereby increasing a heat transfer effect and securing an effect of shortening the temperature increase time.

Additionally, in an atomic layer deposition device according to embodiments of the present invention, since a heater can be attached to a surface of a chamber without being spaced apart from the chamber, it is possible to minimize the loss of heat transferred from a heater.

In addition, an atomic layer deposition device according to embodiments of the present invention can have an advantage of facilitating the maintenance of the deposition device because a heater attached to a surface of a chamber can be detached, attached, and easily replaced.

Additionally, in an atomic layer deposition device according to embodiments of the present invention, since it is possible to control heaters in each zone and at each location on upper, lower, left, and right sides of a chamber separately through a control unit, the temperature can be controlled differently depending on the accommodated location and state of a wafer accommodated inside the chamber, thereby enabling more precise temperature control.

The effects of the present invention are not limited to the effects described above, and other effects that are not described will be clearly understood by those skilled in the art from the description of the claims.

### DESCRIPTION OF DRAWINGS

FIG. 1 is an exploded perspective view showing an atomic layer deposition device on which a heater is disposed according to one embodiment of the present invention.

FIG. 2 is a view showing the heater of FIG. 1 coupled to a chamber.

FIG. 3 is a cross-sectional view along line A-A′ of FIG. 2 and shows a heating pipe built in the heater.

FIG. 4 is a block diagram showing a configuration of the atomic layer deposition device according to one embodiment of the present invention.

FIG. 5 is a block diagram showing the arrangement and control of heaters for each zone according to one embodiment of the present invention.

FIG. 6 is a block diagram showing a structure in which no wafer is disposed in a zone of the outermost portion of a chamber according to one embodiment of the present invention.

FIG. 7 is a graph showing that the temperature of the heater is set higher as the heater is close to an insertion portion of a wafer according to one embodiment of the present invention.

FIG. 8 is an image of an experimental result showing that temperature uniformity is secured for wafers in the chamber when the heater is operated according to one embodiment of the present invention.

### MODES OF THE INVENTION

The present invention may undergo various modifications and have various embodiments, and specific embodiments will be illustrated in the drawings and described in detail in the description of the invention. However, this is not intended to limit the present invention to specific embodiments, and it should be understood that the present invention includes all modifications, equivalents, or substitutes included in the spirit and technical scope of the present invention. In describing the present invention, the same identification numbers are used for the same components even though they are shown in different embodiments.

Hereinafter, embodiments of the present invention will be described in detail with reference to the accompanying drawings, and when describing with reference to the drawings, the same or corresponding components are denoted by the same reference numeral, and overlapping descriptions thereof will be omitted.

In the embodiments below, terms such as “first” and “second” are not intended to be limiting but are used for the purpose of distinguishing one component from another component.

In the embodiments below, a singular expression includes a plural expression unless the context clearly indicates otherwise.

In the embodiments below, terms such as “include” and “have” mean that a feature or component described in the specification is present, and do not exclude in advance the possibility of adding one or more other features or components.

In the drawings, the sizes of components may be exaggerated or reduced for convenience of description. For example, the size and thickness of each component shown in the drawings are arbitrarily shown for convenience of description, and thus the present invention is not necessarily limited to what is shown.

In the case of a certain embodiment that can be implemented in a different way, a specific process sequence may be performed in a sequence other than that described. For example, two processes described sequentially may be performed substantially simultaneously, or may proceed in reverse order from that described.

Terms used in this application are used only to describe particular embodiments and are not intended to limit the present invention. In this application, it should be understood that terms such as “include” and “have” are intended to specify that a feature, number, step, operation, component, part, or combination thereof described in the specification is present, and do not exclude in advance the possibility of the presence or addition of one or more other features, numbers, steps, operations, components, parts or combinations thereof.

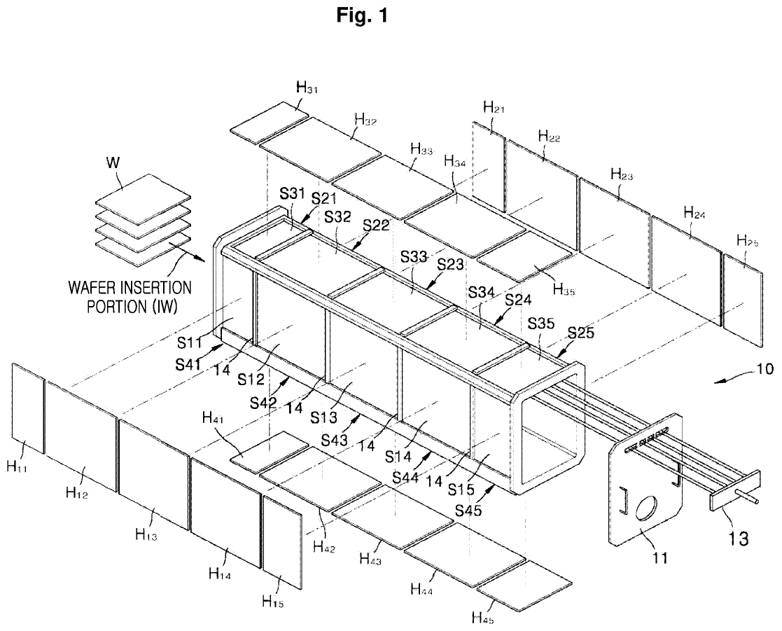

An atomic layer deposition device according to embodiments of the present invention will be described below with reference to FIGS. 1 to 5.

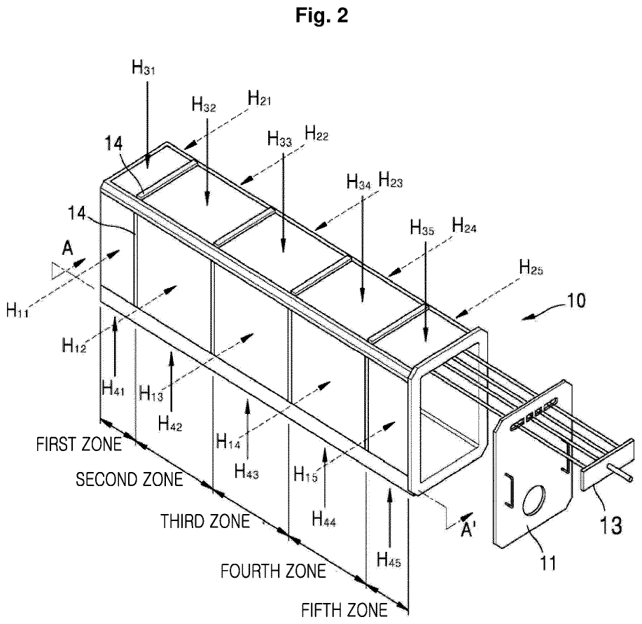

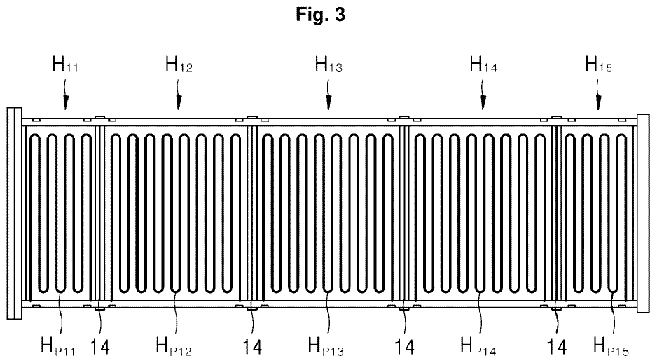

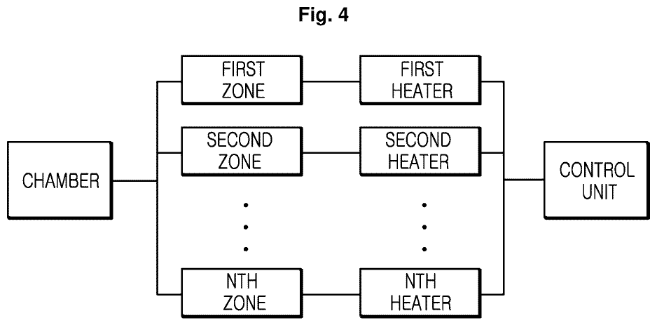

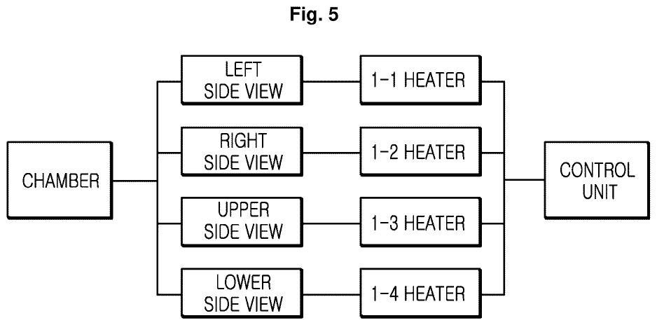

FIG. 1 is an exploded perspective view showing the atomic layer deposition device on which a heater is disposed according to one embodiment of the present invention. FIG. 2 is a view showing the heater of FIG. 1 coupled to a chamber. FIG. 3 is a cross-sectional view along line A-A′ of FIG. 2 and shows a heating pipe built in the heater. FIG. 4 is a block diagram showing a configuration of the atomic layer deposition device according to one embodiment of the present invention. FIG. 5 is a block diagram showing the arrangement and control of heaters for each zone according to one embodiment of the present invention.

Referring to FIGS. 1 to 5, the atomic layer deposition device according to one embodiment of the present invention includes a chamber 10 for storing a plurality of wafers W, a plurality of heaters H disposed on a surface of the chamber 10, and a control unit for controlling the power, temperature, etc. of each of the heaters H. In this case, the chamber 10 may be divided into a plurality of zones. For example, the chamber 10 is divided into the plurality of zones along an extension direction (a first direction) of the chamber 10, the plurality of heaters H are disposed in each of the plurality of zones of the chamber 10, and the control unit controls the plurality of heaters separately.

A plurality of wafers W may be inserted into the chamber 10. A deposition process may be performed on the wafers by injecting a process gas into the chamber 10 into which the plurality of wafers W are inserted.

According to the present embodiment, the chamber may be formed in an elongated rectangular parallelepiped shape. In this case, a rear cover 11 and a supply line unit 13 including a plurality of pipes extending into the chamber 10 may be formed at one end of the chamber 10 in a longitudinal direction. The supply line unit 13 may supply the process gas, such as trimethylaluminum (TMA) or Al(CH₃)₃), into the chamber 10.

The plurality of wafers W may be inserted into the chamber through a side opposite to the rear cover 11. After insertion of the plurality of wafers W is completed, a door (not shown) closes a portion through which the plurality of wafers W are inserted, thereby sealing the inside of the chamber 10.

The atomic layer deposition process according to the present embodiment is a process of thermally decomposing gas flowing into the chamber 10 in a vacuum state and depositing the decomposed gas as an atomic layer. For thermal decomposition, uniform temperature transfer into the chamber is essentially required. Additionally, during a temperature increase process, it is necessary to shorten the time to stably reach a desired temperature.

Generally, a heater is disposed outside the chamber at a location away from the chamber to increase the temperature of the chamber, but when the heater is disposed at a location away from the chamber, it is difficult for heat to be uniformly transferred to the chamber, and considerable heat loss occurs because the heater has to pass through an air layer during the heat transfer process.

Accordingly, in the atomic layer deposition device according to the present embodiment, since each of the heaters H is disposed on a surface S of the chamber 10, direct heat conduction between the heater H and the surface S is induced, which minimizes the loss of heat generated from the heater H and maximizes the heat transfer effect, thereby shortening the temperature increase time in the chamber 10. For example, the heater H may be disposed in contact with the surface S of the chamber 10. In detail, the heater H may be disposed in direct contact with the surface S of the chamber 10.

In addition, through a structure in which the heaters H are disposed to surround the entire surface of the chamber 10, the atomic layer deposition device may have the advantage of allowing the heat to be uniformly transferred into the chamber 10.

Additionally, in the atomic layer deposition device according to the present embodiment, since a system in which heaters are respectively disposed in the plurality of zones divided in the chamber 10 and the heaters are separately controlled through the control unit is introduced, temperature control may be individually performed according to the accommodated location and state of the wafer accommodated in the chamber 10, thereby enabling more precise temperature control of the chamber 10.

According to the present embodiment, a temperature sensor (not shown) may be disposed inside the chamber 10. In this case, the control unit compares a preset standard temperature value with a temperature value inside the chamber, which is measured through the temperature sensor, and when there is a difference between the preset standard temperature value and an actual temperature value inside the chamber, the temperature of the heater may be increased to compensate for the temperature difference value. In addition, the temperature sensor may be disposed in each zone or at each location in one zone, and when there is a difference between the temperature measurement value at each location, which is measured by the temperature sensor disposed at each location, and the preset standard temperature value, a difference between the temperature value at one location and the standard temperature value is compared with a difference between the temperature value at another location and the standard temperature value, and the temperature to be increased at each location is varied by reflecting the difference that varies at each location, and thus the heater corresponding to each location can be individually controlled.

Referring to FIG. 3, a heating pipe Hp is built in each of the plurality of heaters H according to the present embodiment. The heating pipe Hp is uniformly disposed in the heater H in a zigzag structure so that the heater H uniformly transfers heat to the chamber 10.

A plurality of wafers W may be accommodated in each of the plurality of zones (a first zone, a second zone, . . . , and an N^{th} zone) divided in the chamber 10. The control unit may control the heater in each zone differently depending on the status of the wafers W accommodated in each zone.

According to the present embodiment, as shown in FIGS. 1 and 2, one of the plurality of zones of the chamber 10 includes a left side portion S1, a right side portion S2, an upper side portion S3, and a lower side portion S4, and heaters H1, H2, H3, and H4 are disposed in the left side portion S1, the right side portion S2, the upper side portion S3, and the lower side portion S4, respectively. In this case, the control unit may control each of the heaters H1, H2, H3, and H4 separately.

That is, the chamber 10 according to the present embodiment has a rectangular parallelepiped structure having upper, lower, left, and right sides, the heaters may be separately disposed on the upper, lower, left, and right sides, and the heaters disposed on the upper, lower, left, and right sides may be separately controlled. Therefore, when local temperature control is required for each location of the plurality of wafers W accommodated in the chamber 10, temperature control in the chamber 10 may be performed more precisely by controlling the temperatures of the heaters disposed on the upper, lower, left, and right sides differently.

According to the present embodiment, the plurality of heaters H may be attached to or detached from the chamber 10. More specifically, the plurality of heaters H individually mounted in the zones of the chamber 10 may be individually attached to or detached from the chamber 10. Additionally, the plurality of heaters H individually mounted on the upper, lower, left, and right sides of one zone of the chamber 10 may be individually attached to or detached from the chamber 10.

For example, the heater H may include a first heater H1 disposed on the left side portion S1 of the chamber 10, a second heater H2 disposed on the right side portion S2 of the chamber 10, a third heater H3 disposed on the upper side portion S3 of the chamber 10, and a fourth heater H4 disposed on the lower side portion S4 of the chamber 10.

Additionally, each of the first to fourth heaters H1, H2, H3, and H4 may include a plurality of sub-heaters sequentially disposed in the first direction. For example, the first heater H1 may include a plurality of sub-heaters H11, H12, H13, H14, and H15 sequentially disposed in the first direction on the left side portion S1, and the second heater H2 may include a plurality of sub-heaters H21, H22, H23, H24, and H25 sequentially disposed in the first direction on the right side portion S2. Additionally, the third heater H3 may include a plurality of sub-heaters H31, H32, H33, H34, and H35 sequentially disposed in the first direction on the upper side portion S3, and the fourth heater H4 may include a plurality of sub-heaters H41, H42, H43, H44, and H45 sequentially disposed in the first direction on the lower side portion S4.

The number of sub-heaters included in each of the first to fourth heaters H1, H2, H3, and H4 may correspond to the number of zones divided in the chamber 10. For example, when the chamber 10 is divided into five zones (first to fifth zones), each of the heaters H1, H2, H3, and H4 may include five sub-heaters (first to fifth sub-heaters).

Additionally, the sub-heaters included in each of the first to fourth heaters H1, H2, H3, and H4 may be spaced apart from the adjacent sub-heaters in the first direction or may come into contact with each other due to thermal expansion when heated. Here, the first direction may be a direction from the door (not shown) toward the rear cover 11 in the extension direction of the chamber 10.

The chamber 10 may include a heater fixing portion 14 that fixes the heater H to the chamber 10. The heater fixing portion 14 may be disposed on the outer surface of the heater H such that the heater H is in close contact with the chamber 10. The heater fixing portion 14 may press the heater H from the outside to the inside of the chamber 10. The heater fixing portion 14 may maximize a surface contact area of the heater H with the outer surface of the chamber 10 to improve the thermal conductivity of heat transferred from the heater H to the chamber 10.

The chamber 10 may include a heater fixing portion 14 protruding to divide each zone. In this case, each heater H may be mounted between the heater fixing portions 14. In detail, the heater fixing portion 14 may be disposed on a region corresponding to the sub-heater. The heater fixing portion 14 may be disposed on two sub-heaters adjacent to each other in the first direction. For example, the heater fixing portion 14 may be disposed in a region corresponding to a region in the first direction between the sub-heaters included in each of the first to fourth heaters H1, H2, H3, and H4. In this case, a width of the heater fixing portion 14 in the first direction may be larger than a gap between two adjacent sub-heaters. Accordingly, the heater fixing portion 14 may be disposed to press the edge regions of two adjacent sub-heaters such that the heater H is in close contact with the chamber 10.

The number of heater fixing portions 14 disposed on one of the first to fourth heaters H1, H2, H3, and H4 may be less than the number of sub-heaters included in one heater. For example, the number of heater fixing portions 14 disposed on one heater may satisfy m=n'11 with respect to the number of sub-heaters included in one heater (m means the number of heater fixing portions, and n means the number of sub-heaters).

For example, in the case of the heater fixing portions 14 disposed on the first heater H1, the heater fixing portion 14 may be disposed in a region corresponding to a region between the first sub-heater H11 and the second sub-heater H12 of the first heater H1 and in a region corresponding to a region between the second sub-heater H12 and the third sub-heater H13 of the first heater H1. Additionally, the heater fixing portion 14 may be disposed in a region corresponding to a region between the third sub-heater H13 and the fourth sub-heater H14 of the first heater H1 and in a region corresponding to a region between the fourth sub-heater H14 and the fifth sub-heater H15 of the first heater H1.

Alternatively, the number of heater fixing portions 14 disposed on one of the first to fourth heaters H1, H2, H3, and H4 may be equal to the number of sub-heaters included in one heater. For example, the number of heater fixing portions 14 disposed on one heater may satisfy m=n with respect to the number of sub-heaters included in one heater (m means the number of heater fixing portions, and n means the number of sub-heaters). In this case, the heater fixing portion 14 may be disposed in a region corresponding to the center region of the sub-heater to press the heater H.

In this way, through the heater system in which the heaters are separately attached to the zones of the chamber 10 and the upper, lower, left, and right sides of one zone, even when one of the plurality of heaters is broken or damaged, only the corresponding heater can be simply removed and replaced with a new or repaired heater, and thus the usability of the chamber having the heaters mounted thereon can be enhanced. That is, by modularizing the heaters mounted in each portion of the chamber 10, the maintainability of the device can be improved by making the heaters to be easily attached to and detached from the chamber 10.

Additionally, referring to the drawing, in one zone of the chamber 10, the shapes of the heaters H1 and H2 disposed on the left side portion S1 and the right side portion S2 may be the same, and the shapes of the heaters H3 and H4 disposed on the upper side portion S3 and the lower side portion S4 may be the same. Accordingly, the heaters H1 and H2 disposed on the left side portion S1 and the right side portion S2 may be produced as one module, and the heaters H3 and H4 disposed on the upper side portion S3 and the lower side portion S4 may be produced as another module, so that, in heater modules that cover one zone of the chamber, only two heater module structures may fully cover one zone formed by the four sides, thereby simplifying the heater module into two modules and improving the replaceability of the heater module.

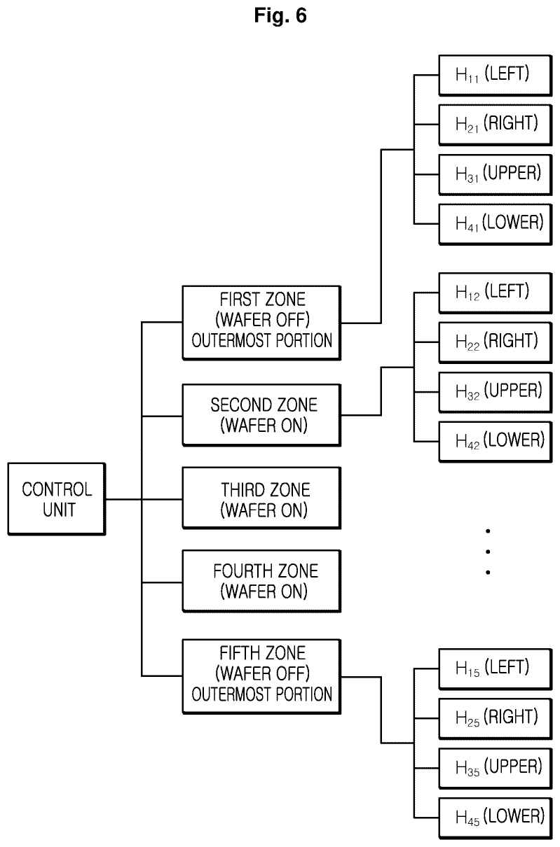

Hereinafter, the structure and features of the outermost zones on both sides of the chamber will be described with reference to FIG. 6. For contents not shown in FIG. 6, refer to the contents shown in FIGS. 1 to 5 and their descriptions.

FIG. 6 is a block diagram showing a structure in which no wafer is disposed in a zone of the outermost portion of the chamber according to one embodiment of the present invention.

Referring to FIGS. 1, 2, and 6, in the atomic layer deposition device according to one embodiment of the present invention, the size of each of the zones located at the outermost portions on both sides of the chamber among the plurality of zones may be smaller than the size of each of the zones located at portions excluding the outermost portions on both sides of the chamber 10. That is, referring to FIG. 2, the size of each of the first and fifth zones may be smaller than the size of each of the second, third, and fourth zones. Here, the first zone may be a zone closest to an insertion portion IW of the wafer W and closest to the door (not shown), and the fifth zone may be a zone farthest from the insertion portion IW of the wafer W and closest to the rear cover 11 of the chamber 10. Additionally, the second to fourth zones may be zones sequentially disposed between the first zone and the fifth zone.

During the wafer deposition process, a plurality of wafers W may be accommodated in the center space of the chamber 10 excluding the spaces at both end portions of the chamber 10. That is, the plurality of wafers W may be accommodated only in the second, third, and fourth zones, excluding the first and fifth zones illustrated in FIG. 2. This is because, in the case of wafers disposed on the outer portion of the chamber during the deposition process, it may be difficult to ensure quality due to the possibility of gas leakage.

According to the present embodiment, the size of each of the zones located at the outermost portions of both sides of the chamber may be smaller than the size of each of the zones disposed in the central portion of the chamber. As a result, it is possible to reduce an extra space area in a portion where wafers are not disposed, thereby improving space utilization.

Accordingly, referring to FIG. 2, the shapes of the heaters H11, H15, H21, and H25 disposed on the left side portions S11 and S15 and the right side portions S21 and S25 of the zones located at the outermost portions on both sides of the chamber may be formed to have smaller sizes than the shapes of the heaters H12, H13, H14, H22, H23, and H24 disposed on the left side portions S12, S13, and S14 and the right side portions S22, S23, and S24 of the zones located in the center portion of the chamber. In addition, the shapes of the heaters H31, H35, H41, and H45 disposed on the upper side portions S31 and S35 and the lower side portions S41 and S45 of the zones located at the outermost portions on both sides of the chamber may be formed to have smaller sizes than the shapes of the heaters H32, H33, H34, H42, H43, and H44 disposed on the upper side portions S32, S33, and S34 and the lower side portions S42, S43, and S44 of the zones located in the central portion of the chamber.

However, in the zones located at the outermost portions on both sides of the chamber, the shapes of the heaters H11, H15, H21, and H25 disposed on the left side portions S11 and S15 and the right side portions S21 and S25 are the same, and the shapes of the heaters H31, H35, H41, and H45 disposed on the upper side portions S31 and S35 and the lower side portions S41, S45 may be the same. Accordingly, the heaters H11, H15, H21, and H25 disposed on the left side portions S11 and S15 and the right side portions S21 and S25 may be produced as one module, and the heaters H31, H35, H41, and H45 disposed on the upper side portions S31 and S35 and the lower side portions S41 and S45 may be produced as another module, and thus, in heater modules that cover one zone of the chamber, only two heater module structures may fully cover one zone formed by the four sides, thereby simplifying the heater module into two modules and improving the replaceability of the heater module.

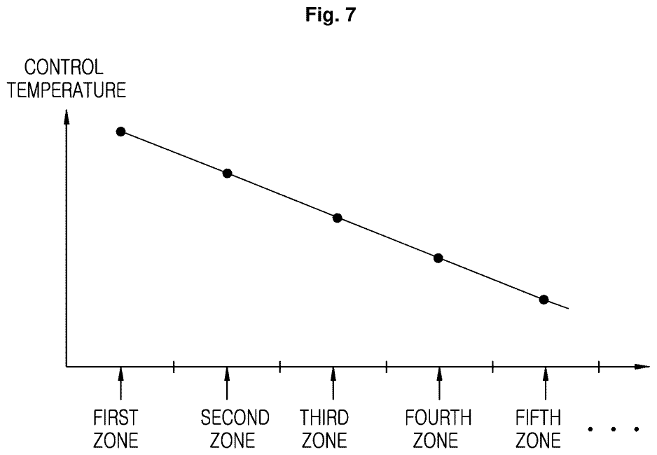

Hereinafter, temperature control according to one embodiment of the present invention will be described with reference to FIG. 7. For contents not shown in FIG. 7, refer to the contents shown in FIGS. 1 to 6 and their descriptions.

FIG. 7 is a graph showing that the temperature of the heater is set higher as the heater is close to the insertion portion of the wafer according to one embodiment of the present invention.

Referring to FIGS. 1 and 7, the control unit may set the temperature of the heater H higher as the heater is close to the insertion portion IW of the wafer. That is, the control unit may set the temperature of the heater H in the first zone closest to the insertion portion IW of the wafer to be higher than the temperature of the heater H in the fifth zone farthest from the insertion portion IW of the wafer. Additionally, the control unit may set the temperature of each of the heaters H of the second to fourth zones located therebetween (between the first and fifth zones) to be a temperature between the temperatures of the heaters H of the first and fifth zones. In the case of the wafer insertion portion IW, this is the portion where the chamber 10 is opened and closed when the wafer is inserted, and thus the greatest amount of heat loss may occur in this portion. Accordingly, according to the present embodiment, the control unit controls the temperature of the heater H to be relatively higher as the heater is close to the insertion portion IW of the wafer, thereby controlling the temperatures of the plurality of wafers W accommodated in the chamber 10 more uniformly. In addition, although FIG. 7 illustrates that the control unit linearly controls the temperature of the heater H to be higher as the heater is close to the insertion portion IW of the wafer, the present invention is not limited thereto, and the control unit may control the temperature non-linearly, in a step shape, etc. depending on the size of the chamber 10, the number of wafers W, the deposition material, etc.

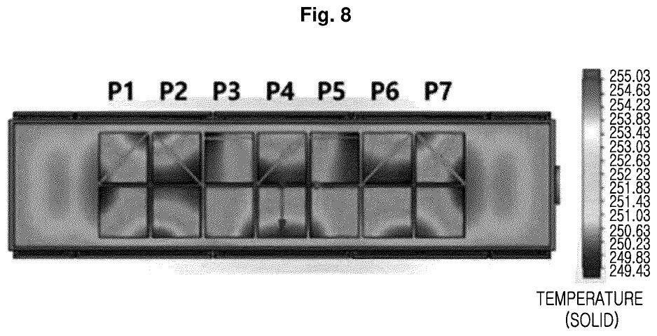

FIG. 8 is an image of an experimental result showing that temperature uniformity is secured for the wafers in the chamber when the heater is operated according to one embodiment of the present invention.

More specifically, FIG. 8 shows an image of an experimental result showing the temperature uniformity in the space where the wafer is located in the chamber when the temperature control of the heater is individually performed for each zone P1, P2, P3, P4, P5, P6, or P7 where the wafer is located in the chamber.

Referring to FIG. 8, it can be seen that the temperature inside the chamber fluctuates within a temperature range of approximately 5 degrees, from a minimum of 249.43 degrees to a maximum of 255.03 degrees. That is, by controlling the temperature of each zone of the chamber individually using the heater according to the present embodiment, the temperature range of the chamber may be maintained at approximately 5 degrees, thereby ensuring temperature uniformity throughout the chamber.

Although the present invention has been described with reference to embodiments illustrated in the drawings, these are merely examples. Those skilled in the art will fully appreciate that various modifications and equivalent other embodiments are possible from the embodiments. Therefore, the true technical protection scope of the present invention should be determined based on the appended claims.

The specific technical content described in the embodiments is only an example and does not limit the technical scope of the embodiments. In order to describe the invention concisely and clearly, descriptions of general techniques and configurations of the related art may be omitted.

Additionally, the connection or absence of connection of lines between components shown in the drawings is merely an example of functional connections and/or physical or circuit connections and may be expressed in an actual device by alternative or additional various functional connections, physical connections, or circuit connections. Additionally, if there is no specific mention such as “essential” or “importantly,” the component may not be a component absolutely necessary for the application of the present invention.

The terms “above,” “the,” and a designator similar thereto, which are used in the description and claims of the invention may refer to both the singular and the plural, unless specifically limited.

In addition, when a range is described in an embodiment, it is considered that the present invention includes an invention to which an individual value belonging to the range is applied (unless otherwise described), and it is the same as describing each individual value constituting the range in the description of the invention.

Additionally, when there is no explicit description or contradiction regarding a sequence of steps constituting a method according to an embodiment, the steps may be performed in any suitable order. The embodiments are not necessarily limited to the sequence in which the above steps are described. The use of any examples or exemplary terms (e.g., “for example,” “etc.”) in the embodiments is merely intended to describe the embodiments in detail and does not limit the scope of the embodiments by virtue of such examples or exemplary terms, unless otherwise limited by the claims. Additionally, a person skilled in the art will appreciate that various modifications, combinations, and changes can be made according to design conditions and factors within the scope of the appended claims or their equivalents.

What is claimed is:

1. An atomic layer deposition device comprising:
a chamber that accommodates a plurality of wafers;
a plurality of heaters disposed on a surface of the chamber; and
a control unit that controls the heaters,
wherein the chamber is divided into a plurality of zones in a first direction defined as an extension direction of the chamber,
the plurality of heaters are disposed in each of the plurality of zones of the chamber, and
the control unit controls temperatures of the plurality of heaters separately.

2. The atomic layer deposition device of claim 1, wherein one zone of the plurality of zones of the chamber includes a left side portion, a right side portion, an upper side portion, and a lower side portion,
the heater is disposed on each of the left side portion, the right side portion, the upper side portion, and the lower side portion, and
the control unit controls the heater disposed on each of the left side portion, the right side portion, the upper side portion, and the lower side portion separately.

3. The atomic layer deposition device of claim 2, wherein, in the one zone, shapes of the heaters disposed on the left side portion and the right side portion are the same, and shapes of the heaters disposed on the upper side portion and the lower side portion are the same.

4. The atomic layer deposition device of claim 1, wherein a size of each zone located at outermost portions on both sides of the chamber among the plurality of zones is smaller than a size of each zone located at portions excluding the outermost portions on both sides of the chamber.

5. The atomic layer deposition device of claim 4, wherein the plurality of wafers are disposed in zones excluding the zones located at the outermost portions on both sides of the chamber among the plurality of zones.

6. The atomic layer deposition device of claim 1, wherein the plurality of zones include:
a first zone that is closest to an insertion portion (IW) of the wafer; and
a fifth zone that is farthest from the insertion portion (IW) of the wafer, and
the control unit sets a temperature of the first zone higher than a temperature of the fifth zone.

7. The atomic layer deposition device of claim 1, wherein a heating pipe (Hp) is disposed in the plurality of heaters.

8. The atomic layer deposition device of claim 1, wherein each of the plurality of heaters includes a plurality of sub-heaters disposed in each of the plurality of zones of the chamber,
the chamber includes a heater fixing portion that fixes the heater to the chamber, and
the heater fixing portion is disposed in a region corresponding to a region between the plurality of sub-heaters adjacent in the first direction.

9. The atomic layer deposition device of claim 1, wherein the plurality of heaters are attached to or detached from the chamber.
